(19) United States
(12) Patent Application Publication
(10) Pub. No.: US 2024/0421042 A1
(43) Pub. Date: Dec. 19, 2024

(54) INTEGRATED CIRCUIT DEVICE WITH VERTICAL VIA PIN

(71) Applicant: Intel Corporation, Santa Clara, CA (US)

(72) Inventor: Jung Kyu Chae, Incheon (KR)

(73) Assignee: Intel Corporation, Santa Clara, CA (US)

(21) Appl. No.: 18/333,711

(22) Filed: Jun. 13, 2023

(51) Int. Cl. H01L 23/49

(52) U.S. Cl. CPC H01L 23/49

(57) ABSTRACT

An IC device (e.g., a standard cell) may have one or more vertical via pins for power supply or signal transmission. The IC device may also include semiconductor structures stacked over each other along the vertical axis of the IC device and electrodes stacked over each other along the horizontal axis. An electrode may be a gate electrode over a channel region of a transistor or a trench electrode over a source region or drain region of a transistor. A vertical via pin may be connected to a gate electrode or trench electrode. A vertical via pin may be an input pin or output pin. A vertical via pin may have a longitudinal axis that is perpendicular or substantially perpendicular to the horizontal axis and the vertical axis of the IC device. The IC device may have an EEQ cell that includes cells having different layouts of vertical via pins.

### BACKGROUND

Integrated circuit (IC) fabrication usually includes two stages. The first stage is referred to as the front-end of line (FEOL). The second stage is referred to as the back-end of line (BEOL). In the FEOL, individual semiconductor devices components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

Standard cell methodology is a popular method of designing IC devices, such as application-specific ICs. A standard cell usually includes a group of transistors and interconnect structures. A standard cell may provide a logic function (e.g., AND, OR, XOR, etc.), storage function (e.g., flipflop, latch, etc.), other types of functions, or some combination thereof. A standard cell usually has one or more pins for connecting the IC with another device, such as a printed circuit board (PCB), and so on. The pin can facilitate transmission of electrical signals between the IC and the other device, allowing the IC to communicate with one or more components in the other device. An IC may have multiple pins corresponding to different types of signals or functions, such as power supply, ground, input, output, clock, and so on. The design and layout of pins can be critical to the performance and reliability of the IC.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example IC device with vertical via pins, according to some embodiments of the disclosure.

FIG. 2 illustrates a perspective view of a pair of vertical via pins in an IC, according to some embodiments of the disclosure.

FIG. 3 illustrates an example IC device with long pins, according to some embodiments of the disclosure.

FIG. 4 illustrates an example IC device including a plurality of standard cells, according to some embodiments of the disclosure.

FIG. 5 illustrates an example electrically-equivalent (EEQ) cells with different pin layouts, according to some embodiments of the disclosure.

FIGS. 6A-6B are top views of a wafer and dies that may facilitate one or more IC devices with vertical via pins, according to some embodiments of the disclosure.

FIG. 7 is a side, cross-sectional view of an example IC package that may include one or more IC devices with vertical via pins, according to some embodiments of the disclosure.

FIG. 8 is a cross-sectional side view of an IC device assembly that may include components having one or more IC devices with vertical via pins, according to some embodiments of the disclosure.

FIG. 9 is a block diagram of an example computing device that may include one or more components with one or more IC devices with vertical via pins, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

The height of a standard cell (e.g., the dimension of the cell along the vertical axis) is usually defined as the number of metal tracks that can fit inside the standard cell. The width of a standard cell (e.g., the dimension of the cell along the horizontal axis) is usually defined as the number of polys (polycrystalline silicon) in the horizontal axis. The distance between two parallel polys that are immediately adjacent to each other is referred to as the contacted poly pitch. Scaling of the area of a standard cell can be important to increase the number of transistors in the IC. The standard cell size can be reduced by reducing the poly pitch or the number of routing tracks. However, it can lead to various problems, such as lack of routing resources inside the cell, complexity of cell layout design, poor pin accessibility, aggravation of cell performance and power, and so on.

A solution to the pin accessibility problem is to implement long metal pins in standard cells to improve pin accessibility. However, this solution has limitations in advanced nodes where it is hard to access the entire long metal pin due to the reduced cell size and the aggressive design rule.

For example, even though each long metal pin can be designed with two pin access points, one of the two pin access points cannot be accessed due to the tight design rule, e.g., the edge-to-edge space rule for metal layers. Another disadvantage of the solution is that the parasitic capacitances of pins can be undesirably large due to the enhanced length of the pins. As a result, it also impacts on the performance and power of the cells. Furthermore, this solution fails to address other problems mentioned above, such as lack of routing resources, complexity of cell layout design, and so on.

Embodiments of the present disclosure may improve on at least some of the challenges and issues described above by providing IC devices with vertical via pins. An example IC device may include one or more standard cells. A standard cell may have a horizontal axis and a vertical axis that is perpendicular to the horizontal axis. The standard cell may include semiconductor structures stacked along the vertical axis and electrodes (e.g., gate electrodes, trench electrodes, etc.) stacked over the horizontal axis. The standard cell may further include one or more vertical via pins for coupling the standard cell to another device, e.g., for receiving input signal, transmitting output signal, power supply, and so on. A vertical via pin may be connected to a gate electrode or a trench electrode in a standard cell.

In various embodiments of the present disclosure, a vertical via pin has a longitudinal axis that is perpendicular (or substantially perpendicular) to the vertical axis and horizontal axis of the standard cell. A dimension of the vertical via pin in a direction along its longitudinal axis may be greater than one or more other dimensions of the vertical via pin in one or more other directions. The vertical via pin may also have a transverse cross-section, which may be a cross-section in a plane perpendicular to the longitudinal axis of the structure. The plane may be the same as or parallel to the plane of the vertical axis and horizontal axis of the standard cell. In some embodiments, an IC device may include an EEQ cell comprising a first cell and a second cell. The first cell may be arranged next to the second cell along the horizontal axis of the EEQ cell. The first cell may have a vertical via pin that is misaligned with a vertical via pin in the second cell, e.g., misaligned along the vertical axis of the EEQ cell. The misalignment can optimize accessibility of the vertical via pins.

Vertical via pins in the present disclosure can facilitate optimization of pin access in standard cells. Also, metal usage inside the cell can be reduced. With vertical via pins, the layout of standard cells can be simplified. Routing resources can be saved at cell level and enriched at block level. Further, the pin capacitance of standard cells can be reduced as redundant long metal pins can be avoided. Therefore, the present disclosure provides a more advantageous solution, compared with currently available solutions for pin access, and can improve the performance and power at both cell level and chip level.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of field-effect transistors (FETs), designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” or the phrase “A or B” means (A), (B), or (A and B). For the purposes of the present disclosure, the phrase “A, B, and/or C” or the phrase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

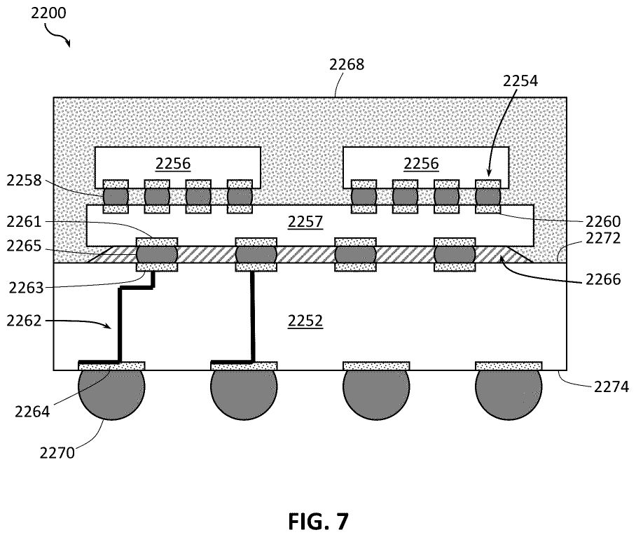

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with vertical via pins as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation.

Operations described may be performed in a different order from the described embodiment.

Various additional operations may be performed, and/or described operations may be omitted in additional embodiments.

Various IC devices with two terminals as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

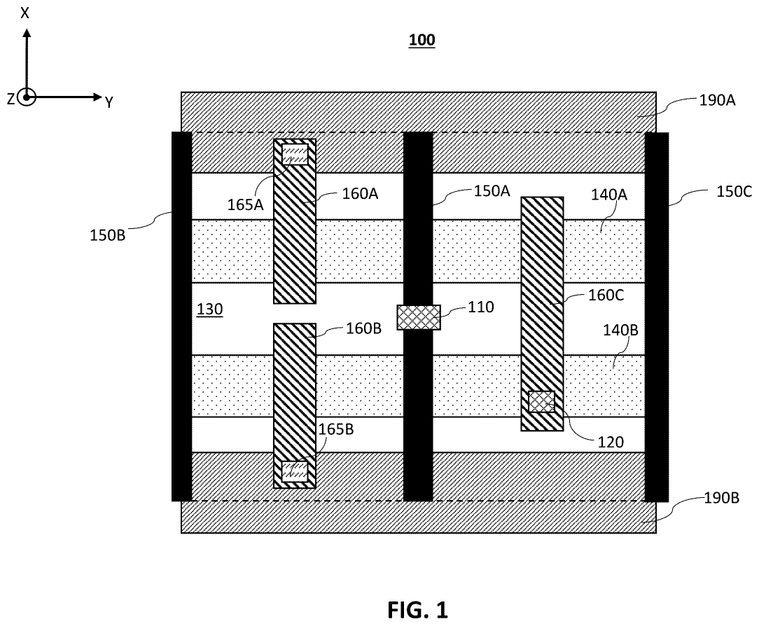

FIG. 1 illustrates an example IC device 100 with vertical via pins 110 and 120, according to some embodiments of the disclosure. The IC device 100 includes a standard cell and a metal layer. The boundaries of the standard cell are represented by dashed lines in FIG. 1. The standard cell includes an electrical insulator 130, semiconductor structures 140A and 140B (collectively referred to as “semiconductor structures 140” or “semiconductor structure 140”), gate electrodes 150A-150C (collectively referred to as “gate electrodes 150” or “gate electrode 150”), trench electrodes 160A-160C (collectively referred to as “trench electrodes 160” or “trench electrode 160”), vias 165A and 165B (collectively referred to as “vias 165” or “via 165”). The metal layer includes metal tracks 190A and 190B (collectively referred to as “metal tracks 190” or “metal track 190”). In other embodiments, the IC device 100 may include different, fewer, or more components. For example, the IC device 100 may include a different number of semiconductor structures, metal tracks, gate electrodes, or trench electrodes. As another example, the IC device 100 may include one or more other metal layers.

FIG. 1 shows an X axis, a Y axis, and a Z axis. The X axis may be the vertical axis of the standard cell. The dimension of the standard cell along the X axis (e.g., the distance between the two opposing boundaries of the standard cell along the Y axis) may be the height of the standard cell. The dimension of the standard cell along the Y axis (e.g., the distance between the two opposing boundaries of the standard cell along the X axis) may be the width of the standard cell. The distance between two adjacent gate electrodes 150 (e.g., the distance between the gate electrodes 150A and 150B or the distance between the gate electrodes 150A and 150C) may be the contacted poly pitch of the standard cell. In some embodiments, the metal layer may be arranged over the standard cell in a direction along the Z axis.

The vertical via pin 110 and the vertical via pin 120 are electrically conductive. The vertical via pin 110 and the vertical via pin 120 may each include one or more electrical conductors, such as metal, and so on. In some embodiments, the vertical via pin 110 and the vertical via pin 120 each have a longitudinal axis, which may be parallel to the Z axis. In some embodiments, a dimension of the vertical via pin 110 or 120 along its longitudinal axis may be greater than the dimension of the vertical via pin 110 or 120 in a direction perpendicular to the longitudinal axis, e.g., in a direction along the X axis or the Y axis. The vertical via pin 110 or 120 may have a transverse cross-section, which may be a cross-section in a plane (e.g., an X-Y plane) perpendicular to its longitudinal axis.

In some embodiments, the vertical via pins 110 and 120 have access points at which the vertical via pins 110 and 120 can be connected to other structures, e.g., electrodes, metal tracks, and so on. An access point may be a point on the vertical via pin 110 or 120. In some embodiments, an access point may be at or proximate to an end of the vertical via pin 110 or 120. The vertical via pin 110 or 120 may have a single access point. As pin accessibility of the vertical via pins 110 and 120 are better than currently available pins, redundant access points on the vertical via pins 110 and 120 may not be needed.

As shown in FIG. 1, the vertical via pin 110 is connected to the gate electrode 150A, and the vertical via pin 120 is connected to the trench electrode 160C. In some embodiments, the vertical via pin 110 or 120 has a single access point, e.g., the point that is connected to the gate electrode 150A or the trench electrode 160C. In some embodiments, the vertical via pin 110 may be an input pin of the standard cell and can support the standard cell to receive signals from one or more other devices. The vertical via pin 120 may be an output pin of the standard cell and can support the standard cell to transmit signals to one or more other devices. The vertical via pin 110 or 120 may couple the gate electrode 150A or the trench electrode 160C to another structure, e.g., a metal track of a metal layer (e.g., M0) arranged over the standard cell in a direction along the Z axis.

In some embodiments, the via 165A or 165B may also be a vertical via pin. The via 165A may have an end connected to the trench electrode 160A and another end connected to the metal track 190A. The via 165B may have an end connected to the trench electrode 160B and another end connected to the metal track 190B. A metal track 190 may also be referred to as a metal line, metal interconnect, or metal structure. In some embodiments, the metal tracks 190 have longitudinal axes that are parallel or substantially parallel to each other. The metal tracks 190 may facilitate power delivery to the standard cell. In some embodiments, the metal tracks 190 may be separated from each other by one or more electrical insulators. The metal tracks 190 may be a power plane and a ground plane, respectively, which can deliver power to the standard cell. In some embodiments, the metal layer including the metal tracks 190 may be M0 in the BEOL section. The IC device 100 may include one or more other metal layers stacked over the metal layer in a direction along the Z axis.

The electrical insulator 130 may separate and insulate semiconductor components or conductive components in the standard cell. In some embodiments, the electrical insulator 130 may wholly or partially wrap one or more other components of the standard cell. For instance, the electrical insulator 130 may wholly or partially wrap the vertical via pin 110 or 120, a semiconductor structure 140, gate electrode 150, trench electrode 160, etc. The electrical insulator 130 may include one or more electrical insulative materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

A semiconductor structure 140 may include one or more semiconductor materials. In some embodiments, a semiconductor structure 140 may be a semiconductor substrate based on which transistors can be formed. In some embodiments, the semiconductor structures 140 may include semiconductors with opposite doping types. For instance, the semiconductor structure 140A may be a N-type semiconductor structure, while the semiconductor structure 140B may be a P-type semiconductor structure. In other embodiments, the semiconductor structures 140 may include semiconductors with the same doping type. In some embodiments, a semiconductor structure 140 may have a planar structure. In other embodiments, a semiconductor structure 140 may have a non-planar structure, such as fin, nanoribbon, and so on.

A semiconductor structure 140 may have a longitudinal axis. In some embodiments, a dimension of the semiconductor structure 140 along its longitudinal axis may be greater than the dimension of the semiconductor structure 140 in a direction perpendicular to the longitudinal axis. For instance, the semiconductor structure 140 may have a longitudinal axis parallel to the Y axis. The dimension of the semiconductor structure 140 along the Y axis may be greater than the dimension of the semiconductor structure 140 along the X axis or the Z axis. The semiconductor structure 140 may also have a transverse cross-section, which may be a cross-section in a plane perpendicular to the its longitudinal axis.

A semiconductor structure 140 may include a source region, channel region, and drain region of a transistor. The channel region may be between the source region and drain region in a direction along the Y axis. The channel region may be over a portion of the gate electrode 150A. The source region may be over a portion of a trench electrode 160. The drain region may be over a portion of another trench electrode 160. For instance, a portion of the semiconductor structure 140A under the trench electrode 160A may be one of the source region and drain region of a transistor, a portion of the semiconductor structure 140A under the gate electrode 150A may be the channel region of the transistor, and a portion of the semiconductor structure 140A under the trench electrode 160C may be the other one of the source region and drain region of the transistor.

Similarly, a portion of the semiconductor structure 140B under the trench electrode 160B may be one of the source region and drain region of a transistor, a portion of the semiconductor structure 140B under the gate electrode 150A may be the channel region of the transistor, and a portion of the semiconductor structure 140B under the trench electrode 160C may be the other one of the source region and drain region of the transistor. The two transistors may be FETs. In an embodiment, the two transistors are both P-type transistors, e.g., P-type metal-oxide-semiconductor (PMOS) transistors. In another embodiment, the two transistors are both N-type transistors, e.g., N-type metal-oxide-semiconductor (NMOS) transistors. In yet another embodiment, one of the two transistors is an N-type transistors, while the other one is a P-type transistors.

A channel region of a transistor may include a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example N-type transistor embodiments (i.e., for the embodiments where a transistor is an NMOS transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 10¹⁵ dopant atoms per cubic centimeter (cm⁻³), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where a transistor is a PMOS transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, n- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)s. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region and drain region in a transistor are connected to the channel region. The source region and drain region may each include a semiconductor material with dopants. In some embodiments, the source region and drain region have the same semiconductor material, which may be the same as the channel material of the channel region. A semiconductor material of the source region or the drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (Cl), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region and the drain region may be highly doped, e.g., with dopant concentrations of about 1·10²¹ cm³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region, and, therefore, may be referred to as “highly doped” (HD) regions.

The channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

A gate electrode 150 includes one or more conductive materials, such as metal, polycrystalline silicon, other types of conductive materials, or some combination thereof. In some embodiments, the choice of the conductive materials in the gate electrode 150 (e.g., the gate electrode 150A) may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, a gate electrode 150 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. In some embodiments, the gate electrode 150B or 150C may be a dummy gate electrode. The gate electrode 150B or 150C may not be coupled to any power plane, ground plane, or signal plane.

A trench electrode 160 may include one or more electrically conductive materials. An electrically conductive material may be metal. Examples of metals in a trench electrode 160 may include, but are not limited to, Ru, Cu, Co, palladium, platinum, nickel, and so on. In the embodiments of FIG. 1, the trench electrode 160A is separated from the trench electrode 160B by the electrical insulator 130. The trench electrode 160A and the trench electrode 160B may be at different electrical potentials during the operation of the IC device 100. The trench electrode 160C may constitute the trench electrodes of two transistors, the source or drain region of which may be subject to the same electrical potential. In other embodiments, the standard cell may include a single trench electrode in lieu of the trench electrodes 160A and 160B. Also, the standard cell may include two separate trench electrodes in lieu of the trench electrode 160C. Even though not shown in FIG. 1, a gate electrode 150 or a trench electrode 160 may be separated from the electrical insulator 130 by a dielectric material. In some embodiments, the gate electrode 150 or trench electrode 160 may be partially or wholly wrapped by the dielectric material.

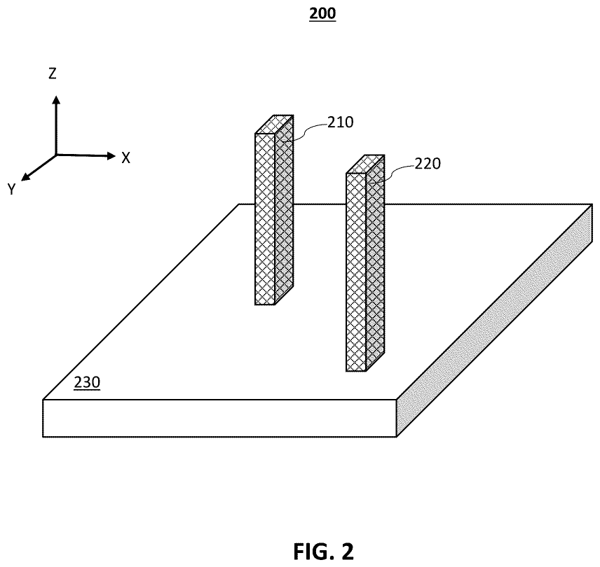

FIG. 2 illustrates a perspective view of a pair of vertical via pins 210 and 220 of a standard cell 200, according to some embodiments of the disclosure. The standard cell 200 may be an embodiment of the standard cell in the IC device 100 in FIG. 1. The vertical via pin 210 may be an embodiment of the vertical via pin 110 in FIG. 1. The vertical via pin 220 may be an embodiment of the vertical via pin 120 in FIG. 1. The standard cell 200 also includes a body 230, which may include one or more semiconductor structures, one or more electrodes, other types of components, or some combination thereof. For the purpose of simplicity and illustration, the components in the body 230 are not shown in FIG. 2.

As shown in FIG. 2, the standard cell 200 has a plane that is parallel or substantially parallel to the X-Y plane. The vertical via pins 210 and 220 each have a longitudinal axis that is parallel or substantially parallel to the Z axis. In some embodiment, an end of the vertical via pin 210 or 220 may be connected to another component of the standard cell, e.g., a gate electrode or a trench electrode. The other end of the vertical via pin 210 or 220 may be connected to a metal layer arranged over the standard cell 200 in a direction along the Z axis.

The vertical via pins 210 and 220 are arranged at the same side of the body 230 along the Z axis in the embodiments of FIG. 2, i.e., the vertical via pins 210 and 220 are both above the body 230 as shown in in FIG. 2. In other embodiments, the vertical via pins 210 and 220 may be both below the body 230 or located at opposite sides of the body 230. The vertical via pins 210 and 220 may be at different levels in some embodiments. In an example, the vertical via pin 210 maybe a via 0 pin, while the vertical via pin 220 may be a via 1 pin. Also, even though FIG. 2 shows two vertical via pins 210 and 220, the standard cell 200 may include a single vertical via pin or more than two vertical via pins. In some embodiments, a super via in the standard cell 200 may be used as a vertical via pin.

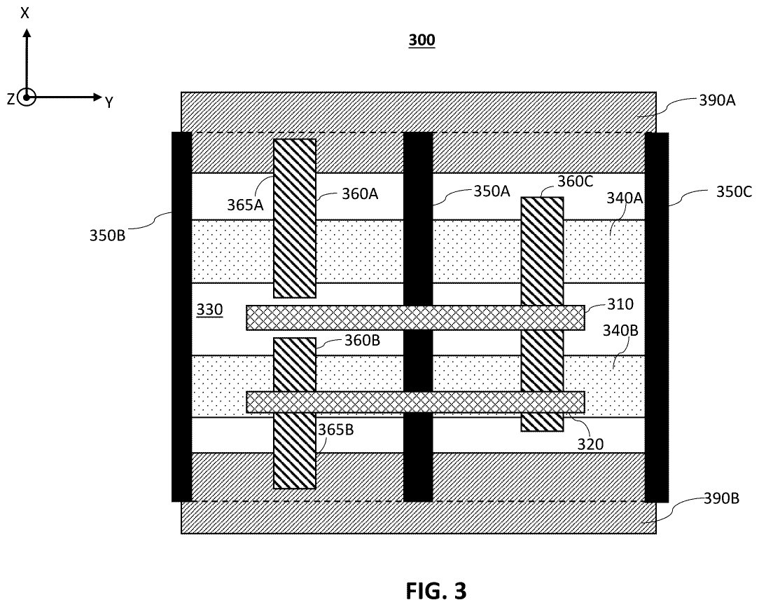

FIG. 3 illustrates an example IC device with pins 310 and 320, according to some embodiments of the disclosure. The IC device 300 includes a standard cell and a metal layer. The boundaries of the standard cell are represented by dashed lines in FIG. 3. The standard cell includes an electrical insulator 330, semiconductor structures 340A and 340B (collectively referred to as “semiconductor structures 340” or “semiconductor structure 340”), gate electrodes 350A-150C (collectively referred to as “gate electrodes 350” or “gate electrode 350”), trench electrodes 360A-360C (collectively referred to as “trench electrodes 360” or “trench electrode 360”), vias 365A and 365B (collectively referred to as “vias 365” or “via 365”). The metal layer includes metal tracks 390A and 390B (collectively referred to as “metal tracks 390” or “metal track 390”). In other embodiments, the IC device 300 may include different, fewer, or more components. For example, the IC device 300 may include a different number of semiconductor structures, metal tracks, gate electrodes, or trench electrodes. As another example, the IC device 300 may include one or more other metal layers.

FIG. 3 shows an X axis, a Y axis, and a Z axis. The X axis may be the vertical axis of the standard cell. The dimension of the standard cell along the X axis (e.g., the distance between the two opposing boundaries of the standard cell along the Y axis) may be the height of the standard cell. The dimension of the standard cell along the Y axis (e.g., the distance between the two opposing boundaries of the standard cell along the X axis) may be the width of the standard cell. The distance between two adjacent gate electrodes 350 (e.g., the distance between the gate electrodes 350A and 350B or the distance between the gate electrodes 350A and 350C) may be the contacted poly pitch of the standard cell. In some embodiments, the metal layer may be arranged over the standard cell in a direction along the Z axis.

The pin 310 and the pin 320 are electrically conductive. The pin 310 and the pin 320 may each include one or more electrical conductors, such as metal, and so on. In some embodiments, the pin 310 and the pin 320 each have a longitudinal axis, which may be parallel to the Z axis. In some embodiments, a dimension of the pin 310 or 320 along its longitudinal axis may be greater than the dimension of the pin 310 or 320 in a direction perpendicular to the longitudinal axis, e.g., in a direction along the X axis or the Y axis. The pin 310 or 320 may have a transverse cross-section, which may be a cross-section in a plane (e.g., an X-Y plane) perpendicular to its longitudinal axis.

As shown in FIG. 3, the pin 310 is connected to the gate electrode 350A, and the pin 320 is connected to the trench electrode 360C. In some embodiments, the pin 310 may be an input pin of the standard cell and can support the standard cell to receive signals from one or more other devices. The pin 320 may be an output pin of the standard cell and can support the standard cell to transmit signals to one or more other devices. The pin 310 or 320 may couple the gate electrode 350A or the trench electrode 360C to another structure, e.g., a metal track of a metal layer (e.g., M0) arranged over the standard cell in a direction along the Z axis.

Different from the vertical via pins 110 and 120 in FIG. 1 or the vertical via pins 210 and 220 in FIG. 1, the pin 310 or 320 has a longitudinal axis along the Y axis. In some embodiments, the pin 310 or 320 may be referred to as a long metal pin. The pin 310 or 320 may include two pin access points for connecting to a metal layer, e.g., M0. However, due to the tight layout of the standard cell in the IC device 300, one of the two pin access points may not be accessible so that one of the two pin access points is available while the other one is redundant. The pin 310 or 320 can require more routing resources (e.g., the amount of metal used for routing, the number of vias needed for routing, etc.) than the vertical via pin 110, 120, 210, or 220. Also, as the pin 310 or 320 is longer than the vertical via pin 110, 120, 210, or 220 along the Y axis, the parasitic capacitance of the pin 310 or 320 is greater than the parasitic capacitance of the vertical via pin 110, 120, 210, or 220. The higher parasitic capacitance can impair the performance and increase power consumption of the IC device 300.

In some embodiments, the vias 365 are coupled to the trench electrodes 360, respectively.

The via 365A may have an end connected to the trench electrode 360A and another end connected to the metal track 390A. The via 365B may have an end connected to the trench electrode 360B and another end connected to the metal track 390B. A metal track 390 may also be referred to as a metal line, metal interconnect, or metal structure. In some embodiments, the metal tracks 390 have longitudinal axes that are parallel or substantially parallel to each other. The metal tracks 390 may facilitate power delivery to the standard cell. In some embodiments, the metal tracks 390 may be separated from each other by one or more electrical insulators. The metal tracks 390 may be a power plane and a ground plane, respectively, which can deliver power to the standard cell. In some embodiments, the metal layer including the metal tracks 390 may be M0 in the BEOL section. The IC device 300 may include one or more other metal layers stacked over the metal layer in a direction along the Z axis. In some embodiments, the trench electrodes 360 may be below the pin 310 or 320 along the Z axis.

The electrical insulator 330 may separate and insulate semiconductor components or conductive components in the standard cell. In some embodiments, the electrical insulator 330 may wholly or partially wrap one or more other components of the standard cell. For instance, the electrical insulator 330 may wholly or partially wrap the pin 310 or 320, a semiconductor structure 340, gate electrode 350, trench electrode 360, etc. The electrical insulator 330 may include one or more electrical insulative materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

A semiconductor structure 340 may include one or more semiconductor materials. In some embodiments, a semiconductor structure 340 may be a semiconductor substrate based on which transistors can be formed. In some embodiments, the semiconductor structures 340 may include semiconductors with opposite doping types. For instance, the semiconductor structure 340A may be a N-type semiconductor structure, while the semiconductor structure 340B may be a P-type semiconductor structure. In other embodiments, the semiconductor structures 340 may include semiconductors with the same doping type. In some embodiments, a semiconductor structure 340 may have a planar structure. In other embodiments, a semiconductor structure 340 may have a non-planar structure, such as fin, nanoribbon, and so on.

A semiconductor structure 340 may have a longitudinal axis. In some embodiments, a dimension of the semiconductor structure 340 along its longitudinal axis may be greater than the dimension of the semiconductor structure 340 in a direction perpendicular to the longitudinal axis. For instance, the semiconductor structure 340 may have a longitudinal axis parallel to the Y axis. The dimension of the semiconductor structure 340 along the Y axis may be greater than the dimension of the semiconductor structure 340 along the X axis or the Z axis. The semiconductor structure 340 may also have a transverse cross-section, which may be a cross-section in a plane perpendicular to the its longitudinal axis.

A semiconductor structure 340 may include a source region, channel region, and drain region of a transistor. The channel region may be between the source region and drain region in a direction along the Y axis. The channel region may be over a portion of the gate electrode 350A. The source region may be over a portion of a trench electrode 360. The drain region may be over a portion of another trench electrode 360. For instance, a portion of the semiconductor structure 340A under the trench electrode 360A may be one of the source region and drain region of a transistor, a portion of the semiconductor structure 340A under the gate electrode 350A may be the channel region of the transistor, and a portion of the semiconductor structure 340A under the trench electrode 360C may be the other one of the source region and drain region of the transistor.

Similarly, a portion of the semiconductor structure 340B under the trench electrode 360B may be one of the source region and drain region of a transistor, a portion of the semiconductor structure 340B under the gate electrode 350A may be the channel region of the transistor, and a portion of the semiconductor structure 340B under the trench electrode 360C may be the other one of the source region and drain region of the transistor. The two transistors may be FETs. In an embodiment, the two transistors are both P-type transistors, e.g., PMOS. In another embodiment, the two transistors are both N-type transistors, e.g., NMOS. In yet another embodiment, one of the two transistors is an N-type transistors, while the other one is a P-type transistors.

A gate electrode 350 includes one or more conductive materials, such as metal, polycrystalline silicon, other types of conductive materials, or some combination thereof. In some embodiments, the choice of the conductive materials in the gate electrode 350 (e.g., the gate electrode 350A) may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, a gate electrode 350 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. In some embodiments, the gate electrode 350B or 350C may be a dummy gate electrode. The gate electrode 350B or 350C may not be coupled to any power plane, ground plane, or signal plane.

A trench electrode 360 may include one or more electrically conductive materials. An electrically conductive material may be metal. Examples of metals in a trench electrode 360 may include, but are not limited to, Ru, Cu, Co, palladium, platinum, nickel, and so on. In the embodiments of FIG. 3, the trench electrode 360A is separated from the trench electrode 360B by the electrical insulator 330. The trench electrode 360A and the trench electrode 360B may be at different electrical potentials during the operation of the IC device 300. The trench electrode 360C may constitute the trench electrodes of two transistors, the source or drain region of which may be subject to the same electrical potential. In other embodiments, the standard cell may include a single trench electrode in lieu of the trench electrodes 360A and 360B. Also, the standard cell may include two separate trench electrodes in lieu of the trench electrode 360C. Even though not shown in FIG. 3, a gate electrode 350 or a trench electrode 360 may be separated from the electrical insulator 330 by a dielectric material. In some embodiments, the gate electrode 350 or trench electrode 360 may be partially or wholly wrapped by the dielectric material.

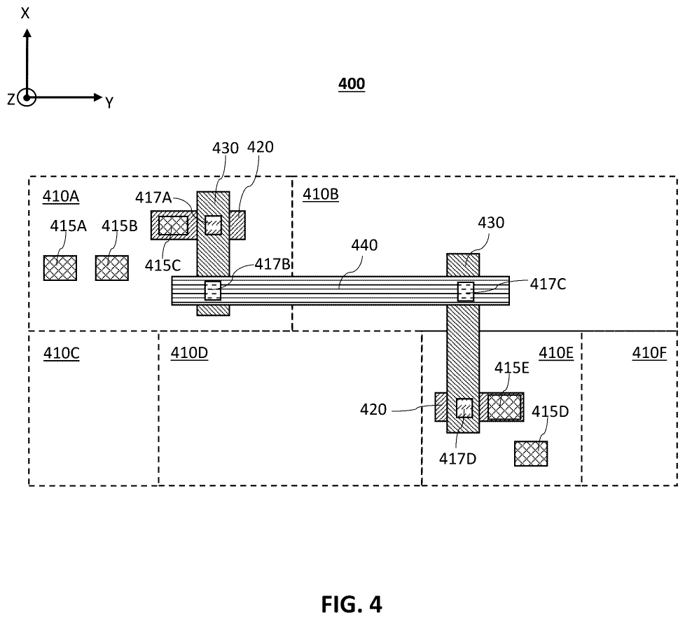

FIG. 4 illustrates an example IC device 400 including a plurality of standard cells 410A-410F, according to some embodiments of the disclosure. The standard cells 410A-410F may be collectively referred to as “standard cells 410” or “standard cell 410.” An embodiment of a standard cell 410 may be the standard cell in the IC device 100 in FIG. 1 or the standard cell in FIG. 2. For the purpose of simplicity and illustration, not all the components in every standard cell 410 are shown in FIG. 4.

In addition to the standard cells 410, the IC device 400 also includes metal layers 420, 430, and 440, which are stacked over at least one standard cell 410 in a direction along the Z axis. In an embodiment, the metal layer 420 may be M0, the metal layer 430 may be M1, and the metal layer 440 may be M2. FIG. 4 shows two metal tracks in the metal layer 420, two metal tracks in the metal layer 430, and a single metal track in the metal layer 440. In other embodiments, the metal layer 420, 430, or 440 may include fewer or more metal tracks.

As shown in FIG. 4, the standard cell 410A has three vertical via pins 415A-415C, and the standard cell 410E has two vertical via pins 415D and 415E. In other embodiments, the IC device 400 may include fewer or more vertical via pins. The location of a vertical via pin may be different from the layout shown in FIG. 4. In some embodiments, the vertical via pins 415A and 415B may be used for input signals of the standard cell 410A. The vertical via pin 415C may be used for output signals of the standard cell 410A. For instance, the vertical via pin 415C may be electrically coupled to the vertical via pin 410E in the standard cell 410E for signal transmission between the two standard cells 410A and 410E. In the embodiments of FIG. 4, the vertical via pin 415C and the vertical via pin 415E are connected to the metal layer 420. The vertical via pin 410E may be an input via pin of the standard cell 410E. The vertical via pin 410D may be an output via pin of the standard cell 410E. In some embodiments, one of more of the vertical via pins 415A-415E may be connected to the metal layer 420 or a different metal layer. In some embodiments, one of more of the vertical via pins 415A-415E may require M0 or M1 routing layer at block level for pin connections, which can optimize the usage of M0 or M1 for pin connections.

The IC device also includes vias 417A-417D (collectively referred to as “vias 417” or “via 417”). In some embodiments, at least one of the vias 417 can facilitate electrical coupling between the metal layers 420, 430, and 440. A via 417 may connect a metal layer to another metal layer. For instance, the via 417A may have an end connected to the metal layer 420 and another end connected to the metal layer 430. The via 417B may have an end connected to the metal layer 430 and another end connected to the metal layer 440. The via 417C may have an end connected to the metal layer 430 and another end connected to the metal layer 440. The via 417D may have an end connected to the metal layer 420 and another end connected to the metal layer 430.

A via 417 may facilitate electrical coupling between an electrode (e.g., gate electrode or trench electrode) in a standard cell 410 to one or more metal layers. For instance, a via 417 may extend from an electrode in a standard cell 410 to a metal layer and further to another metal layer. The vias 417A and 417B may be over the standard cell 410A, the via 417C may be over the standard cell 410B, and the via 417D may be over the standard cell 410C. In other embodiments, some or all of the vias 417 may have different locations. The vias 417 may facilitate power supply or signal transmission. In some embodiments, a via 417 may be a vertical via pin.

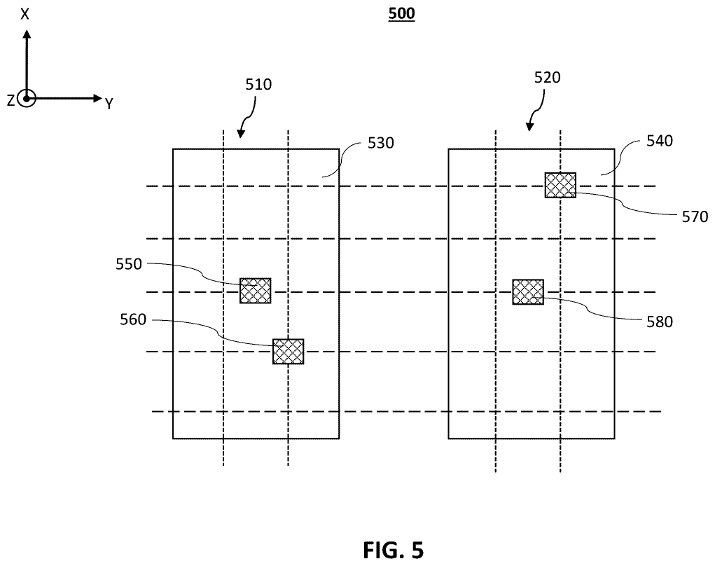

FIG. 5 illustrates an example EEQ cell 500 including cells 510 and 520 with different pin layouts, according to some embodiments of the disclosure. The cell 510 or 520 may be a standard cell, an embodiment of which may be the standard cell in the IC device 100 in FIG. 1, the standard cell 200 in FIG. 2, or a standard cell 410 in FIG. 4. Even though FIG. 5 shows two cells 510 and 520, the EEQ cell 500 may include more than two cells in other embodiments. For the purpose of simplicity and illustration, not all the components in the cells 510 and 520 are shown in FIG. 5. The EEQ cell 500 may be used in a variety of applications, including portable electronic devices, electric vehicles, and renewable energy systems. In some embodiments, the EEQ cell 500 may be used in lieu of the standard cell in the IC device 100 in FIG. 1, the standard cell 200 in FIG. 2, or a standard cell 410 in FIG. 4.

In some embodiments, the cells 510 and 520 are electrically equivalent. The cells 510 and 520 may have the same or substantially similar electrical functions. For instance, the cells 510 and 520 may have the same or substantially similar electrical characteristics, such as voltage or current characteristics. In an example, the cells 510 and 520 may be designed to produce the same or substantially similar electrical output. The cells 510 and 520 can have the same or substantially similar open-circuit voltage (OCV), e.g., the voltage that a cell produces when it is not connected to any external circuit. The cells 510 and 520 may also have the same or substantially similar internal resistance, e.g., the resistance that the cell presents to the flow of current. The cells 510 and 520 may be connected in series or parallel.

In some embodiments, the cells 510 and 520 may have different layouts, physical dimensions, materials, or chemical compositions. As shown in FIG. 5, the cell 510 includes two vertical via pins 550 and 560, and the cell 520 includes vertical via pins 570 and 580. In some embodiments, the vertical via pin 550, 560, 570, or 580 may have a single pin access point. The standard cell with vertical via pin has one access point for each pin. An embodiment of the vertical via pin 550, 560, 570, or 580 may be one of the vertical via pins 110, 120, 210, 220, and 415A-415E. The layout of pins in the cells 510 and 520 are different. Even though the vertical via pins 550 and 580 are aligned in a direction along the Y axis, the vertical via pins 560 and 570 are not aligned along the Y axis. The vertical via pin 560 is below the vertical via pin 550 in the cell 510, but the vertical via pin 570 is above the vertical via pin 580 in the cell 520. The different locations of the vertical via pins 560 and 570 in the cells 510 and 520 can provide better pin access to the EEQ 500.

Even though the location of the vertical via pin 550 in the cell 510 matches the location of the vertical via pin 580 in the cell 520 in FIG. 5, the location of the vertical via pin 550 in the cell 510 may be different from the location of the vertical via pin 580 in the cell 520 in other embodiments. For instance, the vertical via pins 550 and 580 may be misaligned along the Y axis. Also, the cell 510 or 520 may include one or more pins. Also, even though the cells 510 and 520 are stacked over each other along the Y axis, the cells 510 and 520 may be stacked over each other along the X axis in other embodiments.

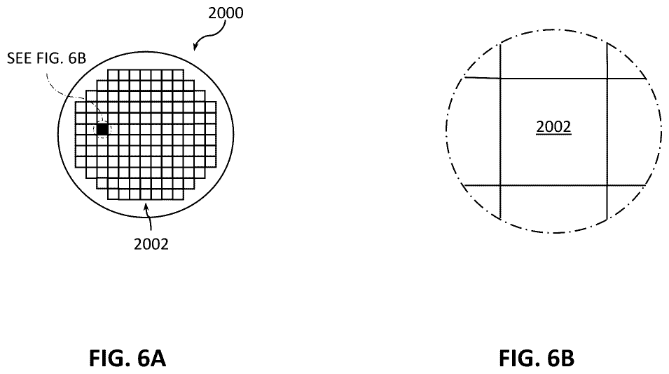

FIGS. 6A-6B are top views of a wafer 2000 and dies 2002 that may facilitate one or more IC devices with vertical via pins, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including two terminals as described herein). After the fabrication of the semiconductor product is complete (e.g., after manufacture of IC devices with vertical via pins as described herein), the wafer 2000 may undergo a singulation process in which each of the dies 2002 is separated from one another to provide discrete “chips” of the semiconductor product. In particular, IC devices with vertical via pins as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the III-N diodes with N-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices with vertical via pins, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

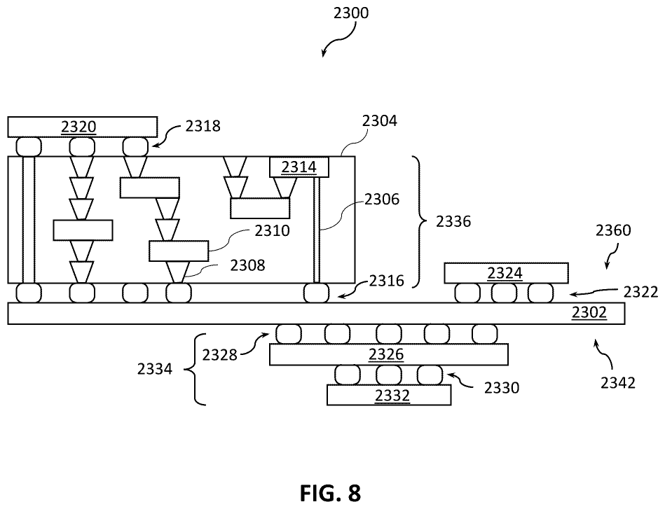

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may facilitate any of the embodiments of IC devices with vertical via pins. In embodiments in which the IC package 2200 includes multiple dies 2256, the IC package 2200 may be referred to as a multi-chip package. Importantly, even in such embodiments of an MCP implementation of the IC package 2200, one or more IC devices with vertical via pins may be provided in a single chip, in accordance with any of the embodiments described herein. The dies 2256 may include circuitry to perform any desired functionality. For example, one or more of the dies 2256 may be ESD protection dies, including one or more IC devices with vertical via pins described herein, one or more of the dies 2256 may be logic dies (e.g., silicon-based dies), one or more of the dies 2256 may be memory dies (e.g., high bandwidth memory), etc. In some embodiments, any of the dies 2256 may include one or more IC devices with vertical via pins, e.g., as discussed above; in some embodiments, at least some of the dies 2256 may not include any III-N diodes with N-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices with vertical via pins, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices having two terminals in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include one or more IC devices with vertical via pins in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 8), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device of FIGS. 1-2), or any other suitable component. In particular, the IC package 2320 may include one or more IC devices with vertical via pins as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices having two terminals as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

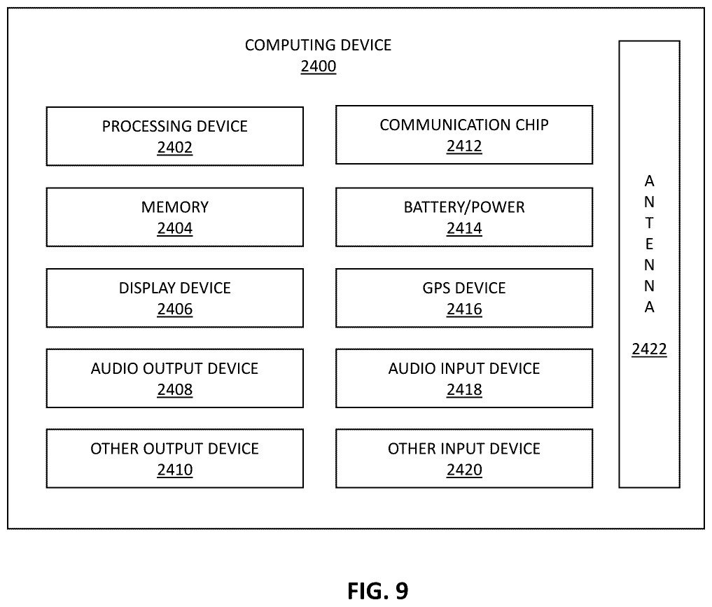

FIG. 9 is a block diagram of an example computing device 2400 that may include one or more components with one or more IC devices with vertical via pins, according to some embodiments of the disclosure. For example, any suitable ones of the components of the computing device 2400 may include a die (e.g., the die 2002 of FIG. 6B) including one or more IC devices with vertical via pins, according to some embodiments of the disclosure. Any of the components of the computing device 2400 may include one or more IC devices with vertical via pins (e.g., any embodiment of IC devices with vertical via pins described above in conjunction with FIGS. 1, 2, 4, and 5) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices having two terminals as described herein may be particularly advantageous for use as part of ESD circuits protecting power amplifiers, low-noise amplifiers, filters (including arrays of filters and filter banks), switches, or other active components.

In some embodiments, IC devices having two terminals as described herein may be used in PMICs, e.g., as a rectifying diode for large currents. In some embodiments, IC devices having two terminals as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a semiconductor structure having a longitudinal axis along a first direction, the semiconductor structure including a first portion, a second portion, and a third portion, where the first portion is between the second portion and the third portion in a second direction perpendicular to the first direction; a first electrode over a first portion of the semiconductor structure in a third direction perpendicular to the first direction or the second direction; a second electrode over a second portion of the semiconductor structure in the third direction; a third electrode over a third portion of the semiconductor structure in the third direction; and an electrically conductive structure connected to one of the first electrode, the second electrode, and the third electrode, where the electrically conductive structure has a longitudinal axis along the third direction.

Example 2 provides the IC device according to example 1, further including an additional electrically conductive structure connected to another one of the first electrode, the second electrode, and the third electrode, where the additional electrically conductive structure has a longitudinal axis along the third direction.

Example 3 provides the IC device according to example 1 or 2, further including a via including a first end and a second end, the first end connected to another one of the first electrode, the second electrode, and the third electrode; and an electrically conductive layer connected to the second end of the via.

Example 4 provides the IC device according to any of the preceding examples, further including an additional semiconductor structure substantially in parallel with the semiconductor structure, where the first electrode is over a portion of the additional semiconductor structure in the third direction, and the electrically conductive structure is connected to the first electrode.

Example 5 provides the IC device according to any of the preceding examples, further including an additional semiconductor structure substantially in parallel with the semiconductor structure, where the second electrode is over a portion of the additional semiconductor structure in the third direction, and the electrically conductive structure is connected to the second electrode.

Example 6 provides the IC device according to example 5, further including a fourth electrode over another portion of the additional semiconductor structure, where the fourth electrode is separated from the third electrode by an electrical insulator.

Example 7 provides the IC device according to any of the preceding examples, where the semiconductor structure has a fin or nanoribbon.

Example 8 provides an IC device, including a first transistor including a first source region, a first drain region, and a first channel region, wherein the first source region is over the first drain region along a horizontal axis of the IC device; a second transistor over the first transistor along a vertical axis of the IC device, the second transistor including a second source region, a second drain region, and a second channel region; a gate structure including a first portion and a second portion, where the first portion is over the first channel region, and the second portion is over the second channel region; and a pin connected to the gate structure, the pin having a longitudinal axis that is substantially perpendicular to the horizontal axis or the vertical axis.

Example 9 provides the IC device according to example 8, where the pin is an input pin of the IC device.

Example 10 provides the IC device according to example 8 or 9, further including a trench electrode including a third portion and a fourth portion, where the third portion is over the first source region or the first drain region, the fourth portion is over the second source region or the second drain region; and an additional pin connected to the trench electrode, the additional pin having a longitudinal axis that is substantially perpendicular to the horizontal axis or the vertical axis.

Example 11 provides the IC device according to example 10, where the additional pin is an output pin of the IC device.

Example 12 provides the IC device according to any one of examples 8-11, further including a trench electrode over the first source region or the first drain region; a metal layer; and an additional pin having a longitudinal axis that is substantially perpendicular to the horizontal axis or the vertical axis, the additional pin connected to the trench electrode and the metal layer.

Example 13 provides the IC device according to example 12, where the metal layer is a power plane.

Example 14 provides the IC device according to example 12 or 13, where the trench electrode is a first trench electrode, the additional pin is a first additional pin and is connected to a first section of the metal layer, and the IC device further includes a second trench electrode and a second additional pin, and the second additional pin has a longitudinal axis that is substantially perpendicular to the horizontal axis or the vertical axis and is connected to the second trench electrode and a second section of the metal layer.

Example 15 provides an IC device, including a first cell including a first electrode over a first source region or a first drain region of a first transistor in a first direction, where the first source region is over the first drain region in a second direction perpendicular to the first direction, and a first pin connected to the first electrode and having a longitudinal axis along the first direction; and a second cell including: a second electrode over a second source region or a second drain region of a second transistor in the first direction, where the second source region is over the second region in the second direction, and a second pin connected to the second electrode and having a longitudinal axis along the first direction, where the first pin is misaligned with the second pin in a third direction perpendicular to the first direction or the second direction.

Example 16 provides the IC device according to example 15, where the first pin or the second pin is an output pin.

Example 17 provides the IC device according to example 15 or 16, where the first cell further includes a third pin having a longitudinal axis along the first direction, the second cell further includes a fourth pin having a longitudinal axis along the first direction, and the third pin and the fourth pin are aligned in the third direction.

Example 18 provides the IC device according to example 17, where the first cell further includes a third electrode over a channel region of the first transistor, and the third pin is connected to the third electrode.

Example 19 provides the IC device according to example 18, where the second cell further includes a fourth electrode over a channel region of the second transistor, and the fourth pin is connected to the fourth electrode.

Example 20 provides the method according to any one of examples 17-19, where the third pin or the fourth pin is an input pin.

Example 21 provides an IC package, including the IC device according to any one of examples 1-20; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-20 may include, or be a part of, at least one of a memory device, a computing device, a wearable device, a handheld electronic device, and a wireless communications device.

Example 24 provides an electronic device, including a carrier substrate; and one or more of the IC devices according to examples 1-20 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides processes for forming the IC device according to any one of claims 1-20.

Example 35 provides processes for forming the IC package according to any one of the claims 21-23.

Example 36 provides processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a semiconductor structure having a longitudinal axis along a first direction, the semiconductor structure comprising a first portion, a second portion, and a third portion, wherein the first portion is between the second portion and the third portion in a second direction perpendicular to the first direction;
a first electrode over a first portion of the semiconductor structure in a third direction perpendicular to the first direction or the second direction;
a second electrode over a second portion of the semiconductor structure in the third direction;
a third electrode over a third portion of the semiconductor structure in the third direction; and
an electrically conductive structure connected to one of the first electrode, the second electrode, and the third electrode, wherein the electrically conductive structure has a longitudinal axis along the third direction.

2. The IC device according to claim 1, further comprising:
an additional electrically conductive structure connected to another one of the first electrode, the second electrode, and the third electrode,
wherein the additional electrically conductive structure has a longitudinal axis along the third direction.

3. The IC device according to claim 1, further comprising:
a via comprising a first end and a second end, the first end connected to another one of the first electrode, the second electrode, and the third electrode; and
an electrically conductive layer connected to the second end of the via.

4. The IC device according to claim 1, further comprising:
an additional semiconductor structure substantially in parallel with the semiconductor structure,
wherein the first electrode is over a portion of the additional semiconductor structure in the third direction, and the electrically conductive structure is connected to the first electrode.

5. The IC device according to claim 1, further comprising:
an additional semiconductor structure substantially in parallel with the semiconductor structure,
wherein the second electrode is over a portion of the additional semiconductor structure in the third direction, and the electrically conductive structure is connected to the second electrode.

6. The IC device according to claim 5, further comprising:
a fourth electrode over another portion of the additional semiconductor structure,
wherein the fourth electrode is separated from the third electrode by an electrical insulator.

7. The IC device according to claim 1, wherein the semiconductor structure has a fin or nanoribbon.

8. An integrated circuit (IC) device, comprising:
a first transistor comprising a first source region, a first drain region, and a first channel region, wherein the first source region is over the first drain region along a horizontal axis of the IC device;
a second transistor over the first transistor along a vertical axis of the IC device, the second transistor comprising a second source region, a second drain region, and a second channel region;
a gate structure comprising a first portion and a second portion, wherein the first portion is over the first channel region, and the second portion is over the second channel region; and
a pin connected to the gate structure, the pin having a longitudinal axis that is substantially perpendicular to the horizontal axis or the vertical axis.

9. The IC device according to claim 8, wherein the pin is an input pin of the IC device.

10. The IC device according to claim 8, further comprising:
a trench electrode comprising a third portion and a fourth portion, wherein the third portion is over the first source region or the first drain region, the fourth portion is over the second source region or the second drain region; and
an additional pin connected to the trench electrode, the additional pin having a longitudinal axis that is substantially perpendicular to the horizontal axis or the vertical axis.

11. The IC device according to claim 10, wherein the additional pin is an output pin of the IC device.

12. The IC device according to claim 8, further comprising:
a trench electrode over the first source region or the first drain region;
a metal layer; and
an additional pin having a longitudinal axis that is substantially perpendicular to the horizontal axis or the vertical axis, the additional pin connected to the trench electrode and the metal layer.

13. The IC device according to claim 12, wherein the metal layer is a power plane.

14. The IC device according to claim 12, wherein:
the trench electrode is a first trench electrode,
the additional pin is a first additional pin and is connected to a first section of the metal layer, and
the IC device further comprises a second trench electrode and a second additional pin, and the second additional pin has a longitudinal axis that is substantially perpendicular to the horizontal axis or the vertical axis and is connected to the second trench electrode and a second section of the metal layer.

15. An integrated circuit (IC) device, comprising:
a first cell comprising:
a first electrode over a first source region or a first drain region of a first transistor in a first direction, wherein the first source region is over the first drain region in a second direction perpendicular to the first direction, and
a first pin connected to the first electrode and having a longitudinal axis along the first direction; and
a second cell comprising:
a second electrode over a second source region or a second drain region of a second transistor in the first direction, wherein the second source region is over the second region in the second direction, and
a second pin connected to the second electrode and having a longitudinal axis along the first direction,
wherein the first pin is misaligned with the second pin in in a third direction perpendicular to the first direction or the second direction.

16. The IC device according to claim 15, wherein the first pin or the second pin is an output pin.

17. The IC device according to claim 15, wherein:
the first cell further comprises a third pin having a longitudinal axis along the first direction,
the second cell further comprises a fourth pin having a longitudinal axis along the first direction, and
the third pin and the fourth pin are aligned in the third direction.

18. The IC device according to claim 17, wherein:
the first cell further comprises a third electrode over a channel region of the first transistor, and
the third pin is connected to the third electrode.

19. The IC device according to claim 18, wherein:
the second cell further comprises a fourth electrode over a channel region of the second transistor, and
the fourth pin is connected to the fourth electrode.

20. The IC device according to claim 17, wherein the third pin or the fourth pin is an input pin.
